(19) United States
(12) Patent Application Publication
(10) Pub. No.: US 2021/0021378 A1
(43) Pub. Date: Jan. 21, 2021

(54) DATA TRANSMISSION METHOD AND DEVICE, AND COMPUTER READABLE STORAGE MEDIUM

(71) Applicant: HKC Corporation Limited, Shenzhen (CN)

(72) Inventors: Dongsheng Guo, Shenzhen (CN); Wei Fu, Shenzhen (CN)

(21) Appl. No.: 17/037,750

(22) Filed: Sep. 30, 2020

Related U.S. Application Data
(63) Continuation of application No. PCT/CN2019/071858, filed on Jan. 16, 2019.

(30) Foreign Application Priority Data
Dec. 28, 2018 (CN) 201811628875.0

(51) Int. Cl. H04L 1/18; H04W 76/11

(52) U.S. Cl. CPC H04L 1/18; H04W 76/11

(57) ABSTRACT

Disclosed are a data transmission method and device, and a computer readable storage medium. The data transmission method includes the following steps: obtaining consecutive duplicate data and repetition number, in data information to be transmitted; replacing the consecutive duplicate data, according to the duplicate data, the repetition number and a preset identifier, to update the data information; and transmitting the updated data information.

### CROSS REFERENCE TO RELATED APPLICATIONS

The present disclosure is a Continuation Application of PCT Application No. PCT/CN2019/071858, filed Jan. 16, 2019, which claims the priority of Chinese Patent Application No. 201811628875.0, filed Dec. 28, 2018 with the National Intellectual Property Administration and entitled “DATA TRANSMISSION METHOD AND DEVICE, AND COMPUTER READABLE STORAGE MEDIUM”, the entirety of which is hereby incorporated herein by reference for all purposes.

### TECHNICAL FIELD

The present disclosure relates to the field of display technology, and more particularly relates to a data transmission method and device, and a computer readable storage medium.

### BACKGROUND

To provide users with high-quality image and clearer dynamic images, and to enhance the video playback effect, the size of the liquid crystal display panel becomes larger and larger, thus the requirements for the resolution and refresh rate of the liquid crystal panel gradually increase.

Due to the improvement of the resolution and the refresh rate of the liquid crystal panel, the amount of data required to be transmitted during the playback of images is drastically increased, resulting in a low data transmission rate. In the prior art, in order to increase the transmission rate, a high-quality transmission medium is used, which increases the data transmission costs.

### SUMMARY

It is one main objective of the present disclosure to provide a data transmission method, a data transmission device and a computer readable medium, aiming to solve the problem in the prior art that data transmission costs are increased as a high-quality transmission medium is used to increase the transmission rate.

In order to realize the above objective, the present disclosure provides a data transmission method, the data transmission method includes: obtaining consecutive duplicate data and repetition number, in data information to be transmitted; replacing the consecutive duplicate data, according to the duplicate data, the repetition number and a preset identifier, to update the data information; and transmitting the updated data information.

Optionally, a logic level of the preset identifier is between a high level and a low level.

Optionally, a logic level of the preset identifier is an average value of a high level and a low level.

Optionally, the operation of replacing the consecutive duplicate data, according to the duplicate data, the repetition number and a preset identifier, to update the data information includes: generating substitute data according to the duplicate data, the repetition number and the preset identifier; and replacing the consecutive duplicate data with the substitute data, to update the data information.

Optionally, the operation of generating substitute data according to the duplicate data, the repetition number and the preset identifier includes: forming the substitute data by the consecutive duplicate data, the preset identifier and the repetition number sequentially; or, forming the substitute data by the consecutive duplicate data and the preset identifiers of the repetition number.

Optionally, the operation of replacing the consecutive duplicate data, according to the duplicate data, the repetition number and a preset identifier, to update the data information includes: generating substitute data according to the repetition number and the preset identifier; and retaining the duplicate data that appears first in the data information, and replacing the other duplicate data with the substitute data, to update the data information.

Optionally, a preset end-repetition identifier is appended after the substitute data, when updating the data information.

Optionally, the data transmission method further includes: determining whether there exists data information after the consecutive duplicate data; and appending a preset end-repetition identifier after the substitute data, when updating the data information, if there exists data information after the consecutive duplicate data.

Optionally, the preset end-repetition identifier includes a plurality of the preset identifiers.

Optionally, the preset end-repetition identifier is different from the preset identifier, and a level of the preset end-repetition identifier is different from the level of the preset identifier.

Optionally, prior to the operation of obtaining consecutive duplicate data and repetition number in data information, the data transmission method further includes: determining whether the consecutive duplicate data exists in the data information; and performing the operation of obtaining consecutive duplicate data and repetition number in data information, if the consecutive duplicate data exists in the data information.

Optionally, prior to the operation of obtaining consecutive duplicate data and repetition number in data information to be transmitted, the data transmission method further includes: determining whether a data transmitting instruction is received; and performing the operation of obtaining consecutive duplicate data and repetition number in data information to be transmitted, if the data transmission instruction is received.

Optionally, prior to the operation of obtaining consecutive duplicate data and repetition number in data information to be transmitted, the data transmission method further includes: detecting a current state of a terminal; and performing the operation of obtaining consecutive duplicate data and repetition number in data information to be transmitted, if the current state of the terminal is a data transmission state.

In another aspect, the present disclosure provides a data transmission device, including: a memory, a processor, and a data transmission program stored on the memory and executable by the processor. The data transmission program when being executed by the processor is configured to perform the operations: obtaining consecutive duplicate data and repetition number, in data information to be transmitted; replacing the consecutive duplicate data, according to the duplicate data, the repetition number and a preset identifier, to update the data information; and transmitting the updated data information.

Optionally, the logic level of the preset identifier is between a high level and a low level.

Optionally, the data transmission program when being executed by a processor is configured to perform the operations: generating substitute data according to the repetition number and the preset identifier; retaining the duplicate data that appears first in the data information, and replacing the other duplicate data with the substitute data, to update the data information.

Optionally a preset end-repetition identifier is appended after the substitute data, when updating the data information.

In still another aspect, the present disclosure provides a computer readable storage medium, storing a data transmission program. The data transmission program when being executed by a processor is configured to perform the operations: obtaining consecutive duplicate data and repetition number, in data information to be transmitted; replacing the consecutive duplicate data, according to the duplicate data, the repetition number and a preset identifier, to update the data information; and transmitting the updated data information.

Optionally, the logic level of the preset identifier is between a high level and a low level.

Optionally, the data transmission program when being executed by a processor is configured to perform the operations: generating substitute data according to the repetition number and the preset identifier; and retaining the consecutive duplicate data that appears for the first time in the data information, and replacing the other duplicate data with the substitute data, to update the data information.

In accordance with the data transmission method and device, and the computer readable storage medium, when receiving the data transmission instruction or detecting that the current state satisfies the data transmission, the data information to be transmitted is obtained, and the consecutive duplicate data and the repetition number of the data are filtered in the data information. After obtaining the consecutive duplicate data and the repetition number, the consecutive and identical consecutive duplicate data in the data information are replaced with the preset identifier combined with the consecutive duplicate data and the repetition number, to update the original data information, and then the updated data information is transmitted, which reduces the amount of data transmission in the data information to be transmitted, and increases the data transmission rate.

### BRIEF DESCRIPTION OF THE DRAWINGS

FIG. 1 is an structure diagram of a terminal of a hardware operating environment involved in an embodiment according to the present disclosure.

FIG. 2 is a flowchart diagram of the data transmission method of an embodiment according to the present disclosure.

FIG. 3 is a waveform diagram of a differential signal in the data transmission method according to the present disclosure.

FIG. 4 is a waveform diagram of another differential signal in the data transmission method according to the present disclosure.

FIG. 5 is a waveform diagram of another differential signal in the data transmission method according to the present disclosure.

FIG. 6 is a waveform diagram of another differential signal in the data transmission method according to the present disclosure.

FIG. 7 is a flowchart diagram of the data transmission method of another embodiment according to the present disclosure.

The realizing of the aim, functional characteristics and advantages of the present disclosure are further described in detail with reference to the accompanying drawings and the embodiments.

### DETAILED DESCRIPTION OF THE EMBODIMENTS

It will be appreciated that the specific embodiments described herein are merely illustrative of the present disclosure and are not intended to limit the present disclosure.

The main solution of the embodiment according to the present disclosure is: obtaining consecutive duplicate data and repetition number, in data information to be transmitted; replacing the consecutive duplicate data, according to the consecutive duplicate data, the repetition number, and a preset identifier, to update the data information; and transmitting the updated data information.

In the related art, high-quality transmission medium is used to improve the transmission rate, which increases costs of data transmission.

In the solution provided in the present disclosure, when receiving the data transmission instruction or detecting that the current state satisfies the data transmission, the data information to be transmitted is obtained, and the consecutive duplicate data and the repetition number of the data are filtered in the data information. After obtaining the consecutive duplicate data and the repetition number, the consecutive and identical consecutive duplicate data in the data information are replaced with the preset identifier combined with the consecutive duplicate data and the repetition number, to update the original data information, and then the updated data information is transmitted, which reduces the amount of data transmission in the data information to be transmitted, and increases the data transmission rate.

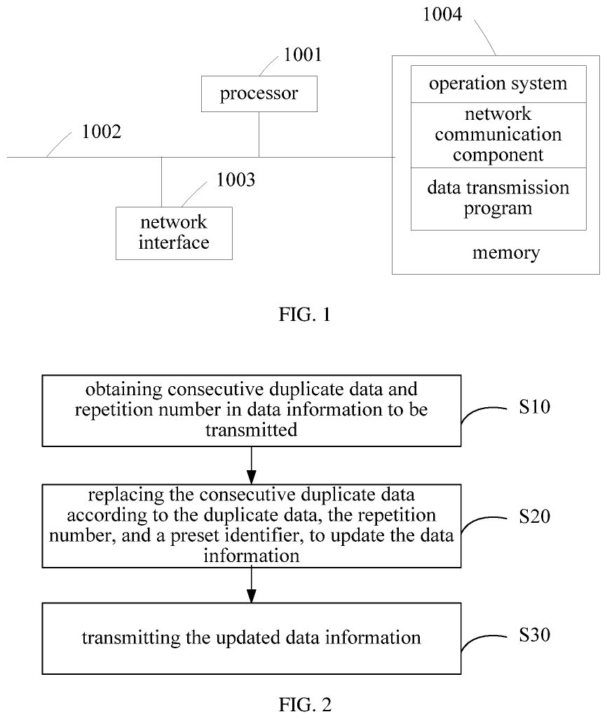

As shown in FIG. 1, FIG. 1 is an structure diagram of a terminal of a hardware operating environment involved in an embodiment according to the present disclosure.

The terminal in the embodiment of the present disclosure may be a server, or may be a mobile terminal device having a data transmission function, such as a personal computer (PC), a television set-top box, a smart phone, a tablet computer, a portable computer, and so on.

As shown in FIG. 1, the terminal may include: a processor 1001, such as CPU, a network interface 1003, a memory 1004, and a communication bus 1002. The communication bus 1002 is configured to facilitate connection and communication between these components. The network interface 1003 may optionally include a standard wired interface, and a wireless interface (such as a WI-FI interface). The memory 1004 may be a high-speed RAM memory, or a non-volatile memory such as a disk memory. The memory 1004 optionally may also be a storage device that is separate from the processor 1001 described above.

Those skilled in the art can understand that the structure of the terminal illustrated in FIG. 1 does not constitute a limitation on the terminal. Thus, the terminal may include more or less components than those illustrated, or some components to be combined, or different arrangements of components.

As shown in FIG. 1, the memory 1004 as a computer storage medium may include an operation system, a network communication component, and a data transmission program.

In the terminal shown in FIG. 1, the network interface 1003 is mainly configured to connect a background server and communicate data with the background server. The processor 1001 may be configured to execute the data transmission program stored in the memory 1004, and perform the following operations:

obtaining consecutive duplicate data and repetition number, in data information to be transmitted;

replacing the consecutive duplicate data, according to the consecutive duplicate data, the repetition number, and a preset identifier, to update the data information; and

transmitting the updated data information.

In some embodiments, the processor 1001 may execute the data transmission program stored in the memory 1004, and further perform the following operation:

the logic level of the preset identifier is between a high level and a low level.

In some embodiments, the processor 1001 may execute the data transmission program stored in the memory 1004, and further perform the following operations:

generating substitute data according to the consecutive duplicate data, the repetition number, and the preset identifier; and

replacing the consecutive duplicate data with the substitute data, to update the data information.

In some embodiments, the processor 1001 may execute the data transmission program stored in the memory 1004, and further perform the following operations:

forming the substitute data by the consecutive duplicate data, the preset identifier and the repetition number sequentially; or,

forming the substitute data by the consecutive duplicate data and the preset identifier of the repetition number.

In some embodiments, the processor 1001 may execute the data transmission program stored in the memory 1004, and further perform the following operations:

generating substitute data according to the repetition number and the preset identifier; and

retaining the consecutive duplicate data that appears for the first time in the data information, and replacing the other consecutive duplicate data with the substitute data, to update the data information.

In some embodiments, the processor 1001 may execute the data transmission program stored in the memory 1004, and further perform the following operation:

a preset end-repetition identifier is appended after the substitute data, when updating the data information.

In some embodiments, the processor 1001 may execute the data transmission program stored in the memory 1004, and further perform the following operation:

the preset end-repetition identifier is a plurality of the preset identifiers.

In some embodiments, the processor 1001 may execute the data transmission program stored in the memory 1004, and further perform the following operations:

determining whether the consecutive duplicate data exist in the data information; and

performing the operation of obtaining consecutive duplicate data and repetition number in data information, when the consecutive duplicate data exist in the data information.

Referring to FIG. 2, the present disclosure provides an embodiment of the data transmission method, the data transmission method includes:

step S10, obtaining consecutive duplicate data and repetition number, in data information to be transmitted;

step S20, replacing the consecutive duplicate data, according to the duplicate data, the repetition number and a preset identifier, to update the data information;

step S30, transmitting the updated data information.

The data transmission method provided by the present disclosure is applied to transmission of computer data, in particular, transmission of data information in the form of differential signals.

When the amount of data in the transmitted data information is large, the transmission rate of the data information will be affected, and the receiving terminal could not receive the data information in time, which affects the implementation of corresponding functions. For example, in the transmission of image information, the data information includes grayscale data of sub-pixels of each pixel in the image, and by transmitting the gray data of all sub-pixels in the entire image, the data receiving terminal receives the complete data information and then display the image. When the pixels of the image are high, the amount of data is large, resulting in slow transmission of the data information, and the image not to be displayed in time.

However, when a large amount of data is included in the data information, a same data is often repeated multiple times. For example, when the chromaticity of an area in the image information is the same, grayscales of the sub-pixels in the area are the same. Generally, each grayscale uses 8-bit data for transmission (8 binary), which is a plenty of consecutive and identical 8-bit binary data as reflected in the data information. If the grayscales of eight consecutive sub-pixels are all 10 gray, there are eight consecutive 00001010 in the data information, that is, multiple groups of 00001010 signals are repeatedly transmitted during the signal transmission.

Therefore, in order to improve the transmission rate of the data signal, the present disclosure provides a data transmission method, which reduces the amount of data in the data information. Specifically, when receiving the data transmission instruction or detecting that the current state satisfies the data transmission, the data information to be transmitted is obtained, and the consecutive duplicate data and the repetition number of the data are filtered in the data information. After obtaining the consecutive duplicate data and the repetition number, the consecutive and identical consecutive duplicate data in the data information are replaced with the preset identifier combined with the consecutive duplicate data and the repetition number, to update the original data information, and then the updated data information is transmitted, which reduces the amount of data transmission in the data information to be transmitted, and increases the data transmission rate.

Specifically, the way for updating the data information is: generating substitute data according to the consecutive duplicate data, the repetition number, and the preset identifier, and replacing the consecutive duplicate data with the substitute data. The substitute data may be composed of the consecutive duplicate data, the preset identifier, and the repetition number sequentially; or the substitute data may also be composed of the consecutive duplicate data and the repetition number of the preset identifier. In the substitute data, the consecutive duplicate data is used to represent the data prototype of the current repetition; the preset identifier is used to represent that the transmitted signal is the consecutive duplicate data; and the repetition number represents the number of signal repetition.

In addition, the logic level of the corresponding transmission signal of the preset identifier is between a high level and a low level, so that a signal receiving terminal may effectively identify the preset identifier. The logic level of the preset identifier is optionally to be an average value of a high level and a low level.

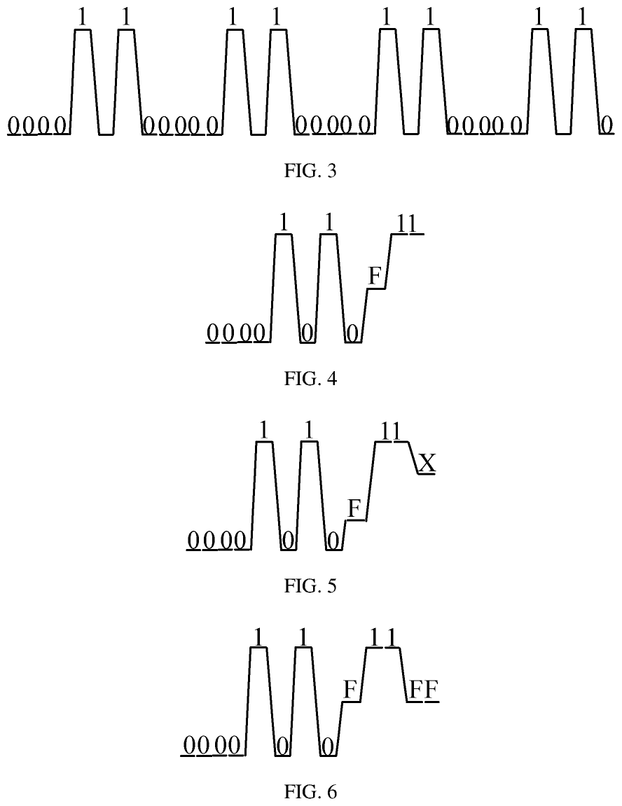

For example, when there is data information that grayscales of four consecutive sub-pixels are all 10 gray in the transmitted data information, there are 00001010000010100000101000001010 (four consecutive 00001010) in the data information, the corresponding differential signal waveform is as shown in FIG. 3. Then, in the original data information, there is consecutive duplicate data 00001010, and the repetition number is 3 (binary code is 11). According to the solution of this embodiment, the substitute data is 00001010F11, or 00001010 FFF, which is generated based on the consecutive duplicate data, the repetition number, and the preset identifier F. Taking 00001010F11 as an example, the corresponding differential signal waveform is shown in FIG. 4. Especially when transmitting a solid color image, all sub-pixels in the data information have the same grayscale, that is, the data information is only composed of a plurality of the consecutive duplicate data. The consecutive duplicate data are replaced with the substitute data, which greatly reduces the data amount, and significantly improves the transmission rate.

From above, it is clear that replacing the continuous and identical data according to the consecutive duplicate data, the consecutive duplicate data, and the preset identifier, so that the amount of data in the updated data information is reduced, thereby increasing the transmission rate of the data information. Under the premise of ensuring the same transmission rate, it is not necessary to adopt a transmission medium with higher transmission performance, which reduces the transmission costs of data, the amount of transmission data, and the number of signal transmissions, thereby reducing power loss.

Further, the preset identifier may be appended with the repetition number to generate the substitute data. When the data information is updated, the consecutive duplicate data that appears for the first time is retained, and the generated substitute data is replaced with the remaining consecutive duplicate data. That is, in the above example, the generated substitute data is F11, or FFF, and the last three consecutive duplicate data 00001010 are replaced with the substitute data. Since the consecutive duplicate data that appears for the first time is retained, the data in the updated data information, corresponding to the consecutive duplicate data that are consecutive identical, is still 00001010F11, or 00001010 FFF.

It should be understood that, when there are multiple consecutive duplicate data in the data information, multiple substitute data are respectively generated for the multiple consecutive duplicate data, and the multiple consecutive duplicate data are respectively replaced with the multiple substitute data, so as to update data information, and reduce the amount of data in the data information.

In this embodiment, when receiving the data transmission instruction or detecting that the current state satisfies the data transmission, the data information to be transmitted is obtained, and the consecutive duplicate data and the repetition number of the data are filtered in the data information. After obtaining the consecutive duplicate data and the repetition number, the consecutive and identical consecutive duplicate data in the data information are replaced with the preset identifier combined with the consecutive duplicate data and the repetition number, to update the original data information, and then the updated data information is transmitted, which reduces the amount of data transmission in the data information to be transmitted, and increases the data transmission rate.

Further, based on the above embodiment, another embodiment of the data transmission method of the present disclosure is proposed.

If the consecutive and identical consecutive duplicate data existing in the data information to be transmitted is intermediate data of the data information, and the substitute data is sequentially formed by using the consecutive duplicate data, the preset identifier F, and the repetition number, during the data transmission, the data signal after the consecutive duplicate data being replaced may be mistaken for the repetition number, so a preset end-repetition identifier is appended after the substitute data. As such, the signal receiving terminal could obtain the repetition number according to the data signal between the preset identifier and the end-repetition identifier, so as to ensure the validity of the data information transmission. If the consecutive and identical consecutive duplicate data are located at the end of the data information, the signal receiving terminal could obtain the repetition number of the consecutive duplicate data according to the data information after the preset identifier, even if there is no end-repetition identifier.

The preset end-repetition identifier may be represented by an identifier different from the preset identifier. The logic levels of the end-repeating identifier and the preset identifier are between a high level and a low level, and the logic levels of the end-repeating identifier and the preset identifier are different.

In addition, due to the existence of multiple level signals, the difference between the level signals is reduced, so that a signal parsing error may occur at the receiving terminal, resulting in data transmission failure. Therefore, the preset end-repetition identifier may be represented by a plurality of the preset identifiers, without introducing no new identifier, thereby ensuring the correct rate of data transmission.

As shown in FIG. 5, the waveform diagram of the differential signal of the substitute data corresponding to FIG. 3 is illustrated, when the preset end-repetition identifier X is taken as the end-repetition identifier.

As shown in FIG. 6, the waveform diagram of the differential signal of the substitute data corresponding to FIG. 3 is illustrated, when two preset identifiers FF are taken as the end-repetition identifier.

In this embodiment, by appending the preset end-repetition identifier after the substitute data, the repetition number could be obtained according to the data signal between the preset identifier and the end-repetition identifier, after receiving the signal, so as to ensure the validity of the data information transmission.

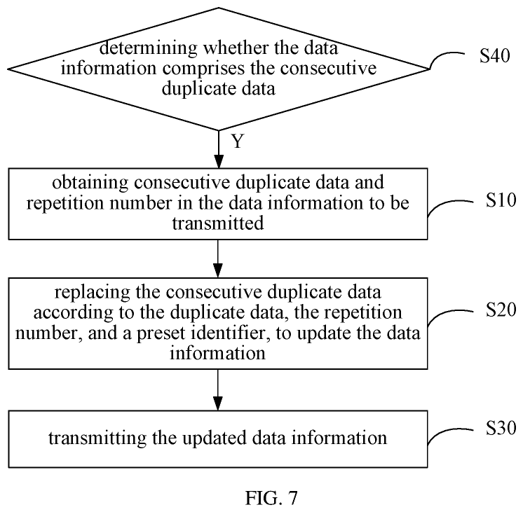

Further, referring to FIG. 7, another embodiment of the data transmission method according to the present disclosure. Base on the foregoing embodiments, before step S10, the data transmission method further includes:

step S40, determining whether the consecutive duplicate data exists in the data information.

If the data information has the consecutive duplicate data, step S10 is performed, that is, the consecutive duplicate data and the repetition number in the signal are obtained.

In a case of data transmission, it is first to obtain the data information to be transmitted, and determine whether there is consecutively identical data in the data information. If there is such data, step S10 and subsequent steps are performed to implement the updating of the data information, which reduces the amount of data of the data information, and improves the data transmission efficiency. If there is no such data, the data information to be transmitted is directly transmitted. By adding the determination that whether there are the consecutive duplicate data, the completeness of the program is ensured, avoiding the situation that the data information fails to be transmitted, when the consecutive duplicate data are not obtained and the data information is then unable to be updated.

In this embodiment, when data transmission is required, it is first to obtain the data information to be transmitted, and determine whether there is continuous and identical data in the data information. If there is consecutively identical data, step S10 and subsequent steps are performed to implement the updating of the data information, which reduces the amount of data of the data information, and improves the data transmission efficiency. If there is no consecutively identical data, the data information to be transmitted is directly transmitted. By adding the determination that whether there are the consecutive duplicate data, the completeness of the program is ensured.

In addition, the present disclosure further provides a data transmission device, including: a memory, a processor, and a data transmission program stored on the memory and executable on the processor, the data transmission program when being executed by the processor performs the steps of the data transmission method as the embodiments described above.

In addition, the present disclosure further provides a computer readable storage medium. The computer readable storage medium stores a data transmission program, the data transmission program when being executed by a processor performs the steps of the data transmission method as the embodiments described above.

It's to be clarified that the term “include”, “comprise” or any other variants thereof is intended to encompass a non-exclusive inclusion, such that a process, method, device, or system including a series of elements not only includes those elements, but also includes other elements that are not explicitly listed, or elements that are inherent to such a process, method, device, or system. In the absence of more restrictions, an element defined by the phrase “including one . . . ” does not exclude the existence of additional identical elements in the process, method, device, or system that includes the element.

The numbers of the embodiments according to the present disclosure are merely for description, and do not represent for the advantages and disadvantages of the embodiments.

According to the description of the above-mentioned embodiments, the skilled in the art can clearly understand that the method of embodiments above may be implemented by means of software plus a necessary general hardware platform, of course, also by means of hardware, but in many cases the former is a better implementation. Based on the understanding, the technical solution of the present disclosure can be embodied in the form of a software product in essence or in part contributing to the prior art. The software product is stored in a storage medium (such as a ROM/RAM, a magnetic disk, an optical disk) as described above, including a plurality of instructions for causing a terminal device (which may be a mobile phone, a computer, a server, an air conditioner, or a network device, and so on.) to execute the method described in various embodiments according to the present disclosure.

The foregoing are only illustrative embodiments in accordance with the present disclosure and therefore not intended to limit the patentable scope of the present disclosure. Any equivalent structure or flow transformations that are made taking advantage of the specification and accompanying drawings of the disclosure and any direct or indirect applications thereof in other related technical fields are within the protection scope of the present disclosure.

What is claimed is:

1. A data transmission method, comprising:
obtaining consecutive duplicate data and repetition number in data information to be transmitted;
replacing the consecutive duplicate data according to the duplicate data, the repetition number and a preset identifier, to update the data information; and
transmitting the updated data information.

2. The data transmission method of claim 1, wherein a logic level of the preset identifier is between a high level and a low level.

3. The data transmission method of claim 1, wherein a logic level of the preset identifier is an average value of a high level and a low level.

4. The data transmission method of claim 1, wherein the operation of replacing the consecutive duplicate data according to the duplicate data, the repetition number and a preset identifier, to update the data information comprises:
generating substitute data, according to the duplicate data, the repetition number and the preset identifier; and
replacing the consecutive duplicate data with the substitute data, to update the data information.

5. The data transmission method of claim 4, wherein the operation of generating substitute data according to the duplicate data, the repetition number and the preset identifier comprises:
forming the substitute data by the duplicate data, the preset identifier and the repetition number sequentially; or,
forming the substitute data by the duplicate data and the preset identifiers of the repetition number.

6. The data transmission method according to claim 1, wherein the operation of replacing the consecutive duplicate data, according to the duplicate data, the repetition number and a preset identifier, to update the data information comprises:
generating substitute data according to the repetition number and the preset identifier; and
retaining the duplicate data that appears first in the data information, and replacing the other duplicate data with the substitute data, to update the data information.

7. The data transmission method according to claim 2, wherein the data transmission method further comprises:
appending a preset end-repetition identifier after the substitute data, when updating the data information.

8. The data transmission method of claim 2, wherein the data transmission method further comprises:
determining whether there exists data information after the consecutive duplicate data; and
in response to determining that there exists data information after the consecutive duplicate data, appending a preset end-repetition identifier after the substitute data, when updating the data information.

9. The data transmission method of claim 7, wherein the preset end-repetition identifier comprises a plurality of the preset identifiers.

10. The data transmission method of claim 7, wherein the preset end-repetition identifier is different from the preset identifier, and a level of the preset end-repetition identifier is different from the level of the preset identifier.

11. The data transmission method of claim 1, wherein before the operation of obtaining consecutive duplicate data and repetition number in data information, the data transmission method further comprises:
determining whether the data information comprises the consecutive duplicate data; and
in response to determining that the data information comprises the consecutive duplicate data, performing the operation of obtaining consecutive duplicate data and repetition number in data information.

12. The data transmission method of claim 1, wherein before the operation of obtaining consecutive duplicate data and repetition number in data information to be transmitted, the data transmission method further comprises:
determining whether a data transmitting instruction is received; and
in response to determining that a data transmitting instruction is received, performing the operation of obtaining consecutive duplicate data and repetition number in data information to be transmitted.

13. The data transmission method of claim 1, wherein before the operation of obtaining consecutive duplicate data and repetition number in data information to be transmitted, the data transmission method further comprises:
detecting a current state of a terminal; and
in response to detecting that the terminal is in a data transmission state, performing the operation of obtaining consecutive duplicate data and repetition number in data information to be transmitted.

14. A data transmission device, comprising: a memory, a processor, and a data transmission program stored in the memory and executable by the processor, the data transmission program when being executed by the processor being configured to perform the following operations:
obtaining consecutive duplicate data and repetition number in data information to be transmitted;
replacing the consecutive duplicate data according to the consecutive duplicate data, the repetition number and a preset identifier, to update the data information; and
transmitting the updated data information.

15. The data transmission device of claim 14, wherein a logic level of the preset identifier is between a high level and a low level.

16. The data transmission device of claim 14, wherein the data transmission program when being executed by the processor is configured to perform the following operations:
generating substitute data according to the repetition number and the preset identifier; and
retaining the duplicate data that appears first in the data information, and replacing the other duplicate data with the substitute data, to update the data information.

17. The data transmission device of claim 16, wherein the data transmission program when being executed by the processor is configured to perform the following operations:
appending a preset end-repetition identifier after the substitute data, when updating the data information.

18. A computer readable storage medium, storing a data transmission program, the data transmission program when being executed by a processor being configured to perform the following operations:
obtaining consecutive duplicate data and repetition number in data information to be transmitted;
replacing the consecutive duplicate data according to the consecutive duplicate data, the repetition number and a preset identifier, to update the data information; and
transmitting the updated data information.

19. The computer readable storage medium of claim 18, wherein a logic level of the preset identifier is between a high level and a low level.

20. The computer readable storage medium of claim 18, wherein the data transmission program when being executed by the processor is configured to perform the following operations:
retaining the duplicate data that appears first in the data information, and replacing the other duplicate data with the substitute data, to update the data information.
